(19) United States
(12) Patent Application Publication
(10) Pub. No.: US 2006/0002189 A1
(43) Pub. Date: Jan. 5, 2006

(54) System and method for determining service availability and soliciting customers

(76) Inventor: William H. Berkman, New York, NY (US)

Correspondence Address: MANELLI DENISON & SELTER, 2000 M STREET NW SUITE 700, WASHINGTON, DC, 20036-3307, US

(21) Appl. No.: 10/881,128

(22) Filed: Jun. 30, 2004

(51) Int. Cl. G11C 11/34; G11C 16/06

(52) U.S. Cl. 365/185.2

(57) ABSTRACT

A system and method for determining service availability and soliciting customers is provided, whereby the availability of a power line communications system for a user is determined and, if the service is available, an offer is provided to that user in an attempt to solicit the user as a customer. A general area of a customer location is determined, and it is determined whether the general area is at least partially coincidental with a service area where a power line communications service is available. If it is determined that the general area is at least partially coincidental with a service area where a power line communications service is available, it is determined if the customer location is enabled for the power line communications service. If it is determined that the customer location is enabled, an offer related to the power line communications service is provided to an entity associated with the customer location.

### FIELD OF THE INVENTION

The invention relates to power line communications systems and similar communications systems generally. More specifically, this invention relates to determining service availability and soliciting customers for such communications systems.

### BACKGROUND OF THE INVENTION

In recent years, there has been a dramatic increase in the popularity of network computing, using networks such as the Internet and other networks. Such networks provide connectivity that is desirable for many applications. As the applications used by such networks have increased in size and complexity, and as high-bandwidth applications have gained increasing popularity, the need for increased-bandwidth communications capabilities within such networks has also increased.

Many people that access networks, such as the Internet, have begun to do so by means other than standard telephone modems or other traditional connections. New connection techniques have been developed, and some are widespread today. For example, digital subscriber line (DSL) is capable of providing increased bandwidth over standard telephone lines. Another popular method for providing access to networks, such as the Internet, uses existing cable television cables, which can provide broadband access to such networks.

In recent years, techniques have been developed for providing communications by way of electrical power distribution systems. These systems are frequently referred to as power line communications systems (PLCS). Because of the ubiquity of standard power lines and the far-reaching infrastructure already in place, there is a tremendous market potential for providing users access to networks, such as the Internet, by way of such power lines. Such access may comprise broadband access. Examples of systems and methods that provide such power line communications systems can be seen, for example, in U.S. patent application Ser. No. 10/641,689, filed Aug. 14, 2003 and entitled “Power Line Communication System and Method of Operating the Same,” which is hereby incorporated by reference herein in its entirety.

Because some power line communications systems are built out gradually, such systems may not be available at all user locations. Additionally, some potential customers, such as existing Internet users, for whom such systems are available and may be desirable, may not know those systems exist or are available to them.

Accordingly, it would be desirable to develop a system and method for determining if service via such power line communications systems is available for one or more given users, and to solicit such users as customers.

### SUMMARY OF THE INVENTION

Accordingly, one or more embodiments of the invention provide a system and method for determining service availability and soliciting customers. For example, according to one or more embodiments, a method is provided that includes determining a general area of a customer location, and determining whether the general area is at least partially coincidental with a service area where a power line communications service is available. If it is determined that the general area is at least partially coincidental with a service area where a power line communications service is available, then it is determined if the customer location is enabled for the power line communications service. If it is determined that the customer location is enabled, an offer related to the power line communications service is provided to an entity associated with the customer location. Finally, this embodiment may also receive and process a response from the entity, such as a request to subscribe to the PLCS service, which may include receiving user information and processing received payment information.

According to another embodiment of the invention, a processor-readable medium including code representing instructions to cause a processor to perform operations is provided. The code is configured to cause the processor to determine if a customer location is enabled for a power line communications service. The code is also configured to cause the processor to provide an offer related to the power line communications service to an entity associated with the customer location, if it is determined that the customer location is enabled.

According to another embodiment of the invention, a method is provided that establishes a communication link with a device and receives information of a network address of the device. The method determines a first geographic area of the device based on the information of the network address and determines if the first geographic area is at least partially coincidental with at least one power line communications service area. If the first geographic area is at least partially coincidental with at least one power line communications service area, an offer related to the power line communications service may be communicated.

Further features of the invention, and the advantages offered thereby, are explained in greater detail hereinafter with reference to specific embodiments illustrated in the accompanying drawings, wherein like elements are indicated by like reference designators.

### BRIEF DESCRIPTION OF THE DRAWINGS

FIG. 1 is a block diagram of an example power line communications system;

FIG. 2 is a block diagram of an example network system;

FIG. 3 is a block diagram of an example network system;

FIG. 4 is a flow diagram of a technique for determining service availability and for providing an offer, according to an example embodiment of the invention;

FIG. 5 is a flow diagram of a technique for determining service availability, according to an example embodiment of the invention;

FIG. 6 is a flow diagram of a technique for determining service availability, according to an example embodiment of the invention;

FIG. 7 is a flow diagram of a technique for determining service availability and for providing an offer, according to an example embodiment of the invention; and

FIG. 8 is a flow diagram of a technique for determining service availability and for communicating an offer, according to an example embodiment of the invention.

### DETAILED DESCRIPTION OF ILLUSTRATIVE EMBODIMENTS

A system and method for determining PLCS service availability and soliciting customers is provided. As will be evident from the description below, many embodiments of the invention utilize the potential customer's network link (e.g., for Internet access link) and therefore, the potential customer is already an existing internet user. Consequently, in such cases, such users have demonstrated a need for network access prior to solicitation.

By way of one or more embodiments of the invention, a customer location (e.g., the location of a user or a user's computer) can be analyzed to determine if service via a power line communications system is available for that customer location. If service via a power line communications system is available for the customer location, then an entity associated with a user (e.g., a user, a user's agent, a user's computer, etc.) can be solicited for such service (e.g., by way of providing an offer, or otherwise communicating an offer). Finally, this embodiment may also receive and process a response from the entity, such as a request to subscribe to the PLCS service, which may include receiving user information and processing received payment information (e.g., credit card data).

According to one or more embodiments of the invention, a customer location associated with a user is determined. This may occur in one of several ways. For example, an administrator of a communications system can dynamically determine this information from a customer Internet protocol (IP) address. Additionally, or alternatively, information regarding a customer location can be obtained from a customer's network service provider (NSP), or another third party. The information associated with the customer location can include, for example, an address of a user or a user's computer, or a general geographic area associated with a user or a user's computer (e.g., city, state, zip code, area code, telephone prefix, etc.).

Next, it is determined whether the customer location is serviceable via the power line communications system. Once it is determined that the user is serviceable by a power line communications system (i.e., that service is available at or around the customer location), the user can be provided an offer in a number of ways. For example, an offer could be provided directly to such a user, by way of email or other network communications, postal mail, telephone, or other suitable technique or presenting the user with offers. Alternatively, an offer can be presented to a user indirectly, such as by way of the user's network service provider. The network service provider can, for example, present the user with a network communication (e.g., email, instant message, etc.), a postal mailing, a telephone call, or the like. Additionally, or alternatively, the network service provider of the user can provide advertising to a user that has been determined to be within a service area of a power line communications system.

An offer can be indirectly presented to a user by way of a third party other than a network service provider, which either communicates directly with the user, or with the user's network service provider. For example, a third party can be used to present the user with an offer by way of a network communication (e.g., email, instant messaging, etc.), postal mail, telephone, or the like. Additionally, or alternatively, a third party can present a user with advertising relating to the offer being provided to the user. For example, online advertising can be presented to a user by a third party when the user accesses the third party's website, either in a traditional, graphical advertisement form (e.g., banner advertisements, pop-up advertisements, etc.), or in other forms (e.g., sponsored links, etc.).

As used herein, the terms “user” and “customer” can be interchanged. For example, a “user” or a “user location” can be referred to as a “customer” or a “customer location,” respectively, as each user with which one or more embodiments of the invention can be used, is considered a potential customer.

As used herein, the term “network service provider” or “NSP” is used for any device, entity, or organization that acts as access point or otherwise provides a user access to an external network, such as the Internet, and/or applications that operate over such a network. For example, an NSP can include an Internet service provider (ISP), an application service provider (ASP), an email server or host, a bulletin board system (BBS) provider or host, a point of presence (POP), a gateway, a proxy server, or other suitable connection point to such a network.

As used herein, the term “offer” refers to a direct or indirect communication to a user, in whatever form, intended to solicit a response from the user to enter into a relationship with the PLCS service provider (e.g., to solicit a user to become a customer of a PLCS service or provide the user with information relating to the PLCS service). Offers are provided or otherwise communicated to users from a computer system such as a web server, email service or other system according to the type of offer provided. Examples of offers may include, but are not limited to: a direct or targeted mailing (electronic or otherwise), a network or electronic communication, a targeted advertisement (electronic or otherwise), instant messaging, short message service messages, a telephone offer, or a personal solicitation (in-person or otherwise).

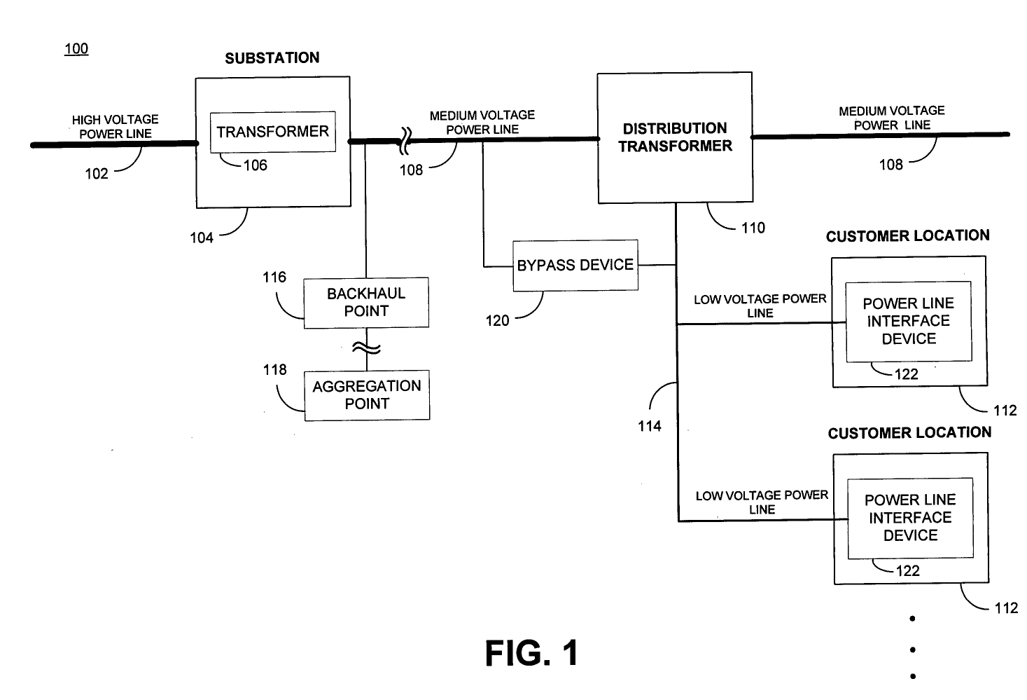

FIG. 1 is a block diagram of an example power line communications system (PLCS) 100. For example, the power line communications system 100 illustrated in FIG. 1 can correspond to one or more systems described in U.S. patent application Ser. No. 10/641,689 (Attorney Docket No. CRNT-0178) incorporated herein by reference. It is by way of such a power line communications system 100 that access to a network (e.g., broadband access), such as the Internet, can be provided using the infrastructure of an existing power distribution system.

In the power line communications system 100, power transmitted from a power generation station (not shown) is carried by way of one or more high-voltage (HV) power lines 102. According to one or more embodiments of the invention, the high voltage power lines 102, which are sometimes referred to as high voltage transmission lines or high-tension lines, can be capable of carrying higher voltages, such as voltages in the range of approximately 69 kV-800 kV. The high voltages carried by way of the high voltage power lines 102 are stepped-down, or converted to a lower voltage, by a substation 104. The substation 104 transforms the voltages received over the high voltage power lines 102 using one or more transformers 106, which are configured to transform the high voltage received to a medium voltage.

Medium voltage power is transmitted by way of one or more medium-voltage (MV) power lines 108, over which it is distributed closer to locations where it is to be used. The medium-voltage power lines 108 may carry voltages in the range of 1 kV-100 kV, depending on the architecture of the electrical power distribution system.

Typically, the voltage from the medium-voltage power line 108 must again be stepped-down prior to being supplied to customer locations. Thus, at various locations where lower voltage is required, a distribution transformer 110 can be provided, which transforms the medium voltage received via a medium voltage power line 108 to low voltage. The low voltage power is transmitted to one or more customer locations 112 by way of one or more low voltage (LV) power lines 114. The lower voltages carried by way of the low voltage power line 114 can include voltages in the range of approximately 100V-240V in the United states, and may comprise other ranges according to the architecture of the electric power distribution system.

This example PLCS includes a backhaul point (BP) 116 that acts as an interface or gateway between the power line communications system 100 and a non-power line telecommunications network (e.g., a fiber optic cable, wireless link, etc.). In this example PLCS, the backhaul point 116 is configured to provide data communications via the medium voltage power line 108. One or more backhaul points 116 can communicate with an aggregation point (AP) 118, which can serve as a point of presence (POP) to a network external to the power line communications system 100, such as the Internet, or other suitable network.

In this example PLCS, data communicated via the medium voltage power line 108 from the backhaul point 116 cannot be reliably transmitted across the distribution transformer 110. Consequently, a bypass device (BD) 120 can be used to communicate the data signal from the medium voltage power line 108 to the low-voltage power line 114. The bypass device 120 can be, for example, a transceiver capable of receiving the data signal from the medium voltage power line 108 and transmitting that data signal to the/low voltage power line 114, and vice versa. One example bypass device comprises a low voltage modem, a medium voltage modem and a router as described in U.S. patent application Ser. No. 10/641,689, which is incorporated by reference above. The bypass device 120 communicates data to and from those customer locations (e.g., homes and/or businesses) that receive power from the low voltage power line to which the bypass device 120 is communicatively connected.

To access the data communicated via the low voltage power line 114 to the one or more customer locations 112, one or more power line interface devices (PLIDs) 122 can be employed at each of the one or more customer locations 112. The power line interface device 122 can be, for example, a power line modem or power line wireless modem, or other device capable of transmitting and receiving data via a low-voltage line 114. For example, according to one or more embodiments of the invention, such a device can be configured to plug into a standard wall power socket (e.g., a 110V socket) and receive or send signals via the wall power socket. Using such a power line interface device 122, data can be both received and transmitted over the power line communications system 100. Thus, data communicated from the power line interface devices 122 can trace the reverse route described above of data received by the power line interface devices 122, and can optionally be communicated to a network outside the power line communications system 100 via the backhaul point 116 and/or the aggregation point 118.

In other PLCSs, data may be communicated via the medium voltage power line and then communicated wirelessly to and from the customer location (e.g., using an IEEE 802 protocol). In other examples PLCSs, the data may be transmitted through the distribution transformer to the customer location (e.g., with or without a repeater on the low voltage power line). In another example PLCS, surface waves are communicated on the medium voltage power line instead of, or in addition to, conventional conductive signals. These PLCSs employ the medium voltage power line. In still another example PLCS, the data may be communicated to and from the customer locations via the low voltage power lines, which are communicatively coupled to a traditional communications medium such as a fiber optic cable, a coaxial cable, a wireless link. Thus, the invention is not limited to a particular PLCS, PLCS architecture, or topology.

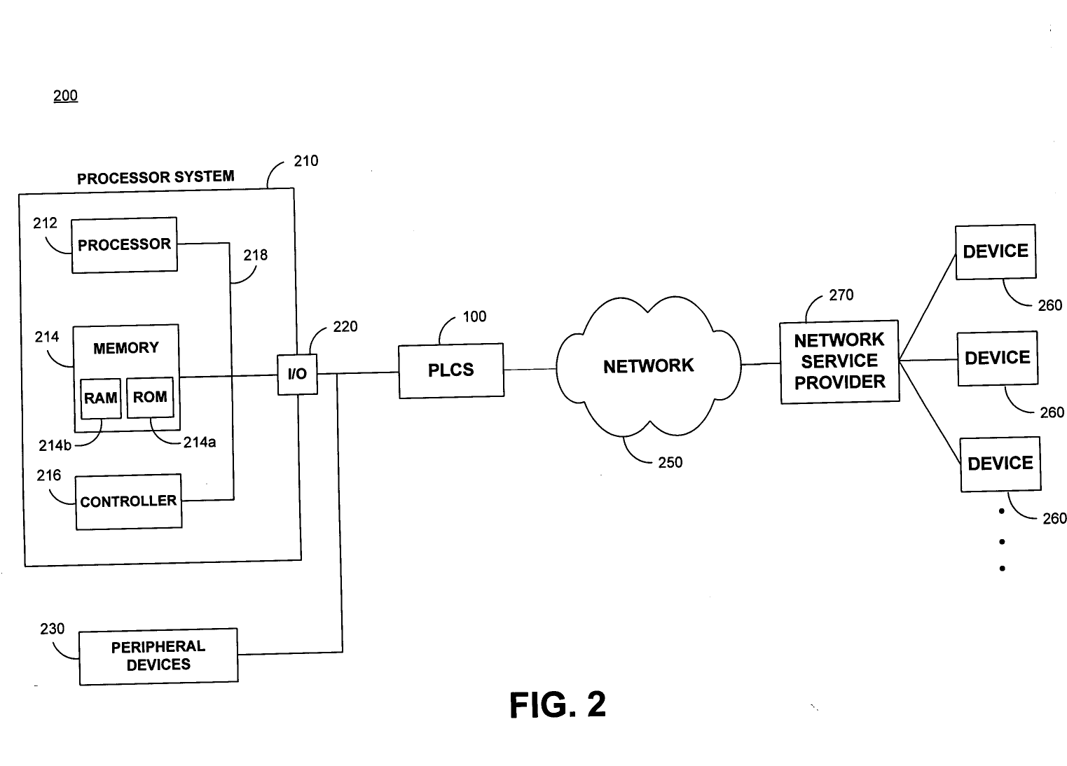

FIG. 2 is a block diagram of an example network system 200 with which one or more embodiments of the invention may be used. The network system 200 shown in FIG. 2 includes a device (processor system 210) that is in communication with the power line communications system 100 (e.g., by way of a PLID 122, etc.). This example device is a processor system 210 capable of communicating via the power line communications system 100, by which it can communicate with one or more devices external to the power line communications system 100. For example, the processor system 210 can communicate via the power line communications system 100 with another network 250 (e.g., the Internet, etc.).

The processor system 210 illustrated in FIG. 2 can be, for example, a commercially available personal computer, a network appliance, a portable electronic device (e.g., electronically device wirelessly connected to a PLID 122), or a less complex computing or processing device (e.g., an IP telephone or a device that is dedicated to performing one or more specific tasks), or any other device capable of communicating via a network, such as the power line communication system 100 or another network 250. Although each component of the processor system 210 is shown as being a single component in FIG. 2, the processor system 210 can include multiple numbers of any components illustrated in FIG. 2. Additionally, multiple components of the processor system 210 can be combined as a single component, where desired.

The processor system 210 includes a processor 212, which according to one or more embodiments of the invention, can be a commercially available microprocessor capable of performing general processing operations. For example, the processor 212 can be selected from the 8086 family of central processing units (CPUs) available from Intel Corp. of Santa Clara, Calif., or other similar processors. Alternatively, the processor 212 can be an application-specific integrated circuit (ASIC), or a combination of ASICs, which is designed to achieve one or more specific functions, or enable one or more specific devices or applications. In yet another alternative, the processor 212 can be an analog or digital circuit, or a combination of multiple circuits.

The processor 212 can optionally include one or more individual sub-processors or coprocessors. For example, the processor can include a graphics coprocessor that is capable of rendering graphics, a math coprocessor that is capable of efficiently performing mathematical calculations, a controller that is capable of controlling one or more devices, a sensor interface that is capable of receiving sensory input from one or more sensing devices, and so forth.

The processor system 210 can also include a memory component 214. As shown in FIG. 2, the memory component 214 can include one or more types of memory. For example, the memory component 214 can include a read only memory (ROM) component 214a and a random access memory (RAM) component 214b. The memory component 214 can also include other types of memory not illustrated in FIG. 2 that are suitable for storing data in a form retrievable by the processor 212, and are capable of storing data written by the processor 212. For example, electronically programmable read only memory (EPROM), erasable electrically programmable read only memory (EEPROM), flash memory, as well as other suitable forms of memory can be included within the memory component 214. The processor 212 is in communication with the memory component 214, and can store data in the memory component 214 or retrieve data previously stored in the memory component 214.

The processor system 210 also can include a controller 216, which can optionally be internal to the processor 212, or external thereto, as shown in FIG. 2. The controller 220 can be configured to control the one or more devices associated with the processor system 210. For example, the controller 216 can be used to configure one or more devices integral to the processor system 210, such as input or output devices, sensors, or other devices configured to form part of the processor system 210. Additionally, or alternatively, the controller 216 can be configured to control one or more devices external to the processor system 210, which may be accessed via an input/output (I/O) component 220 of the processor system 210.

The various components of the processor system 210 can communicate with one another via a bus 218, which is capable of carrying instructions from the processor 212 and/or the controller 216 to other components, and which is capable of carrying data between the various components of the processor system 210. Data retrieved from or written to memory 214 is carried by the bus 218, as are instructions provided by the controller 216 and/or processor 212.

The processor system 210 and its components can communicate with devices external to the processor system 210 by way of an input/output (I/O) component 220 (accessed via the bus 218). According one or more embodiments of the invention, the I/O component 220 can communicate using a variety of suitable communication interfaces. According to one or more embodiments of the invention, the I/O component can include a power line interface device 122 (shown in FIG. 1) configured to communicate with a power line communications system 100. The I/O component 220 also can include, for example, wireless connections, such as infrared ports, optical ports, Bluetooth wireless ports, wireless LAN ports, or the like. Additionally, the I/O component 220 can include, wired connections, such as standard serial ports, parallel ports, universal serial bus (USB) ports, S-video ports, large area network (LAN) ports, small computer system interface (SCSI) ports, and so forth.

By way of the I/O component 220 the processor system 210 can communicate with devices external to the processor system 200, such as peripheral devices 230 that are local to the processor system 210. The I/O component can include a component configured to communicate via one or more communications protocols used for communicating with devices, such as the peripheral devices 230. The peripheral devices 230 in communication with the processor system 210 can include any of a number of peripheral devices 230 desirable to be accessed by or used in conjunction with the processor system 210. For example, the peripheral devices 230 with which the processor system 210 can communicate via the I/O component 220, can include a communications component, processor, a memory component, a printer, a scanner, a storage component (e.g., an external disk drive, database, etc.), or any other device that a user desires to connect to the processor system 210.

The processor system 210 is shown in communication with a power line communications system 100 via the I/O component 220. The processor system 210 can, according to one or more embodiments of the invention, be a device used at a customer location 112 (shown in FIG. 1) that accesses the power line communications system 100 via a power line interface device 112 (shown in FIG. 1). The processor system 210 can communicate with other devices within the power line communications system 100 by way of such an interface device.

The processor system can also communicate with a network 250 external to the power line communications system 100, such as the Internet or other network. For example, the processor system 210 can communicate with the external network 250 by way of a backhaul point 116 (shown in FIG. 1) and/or an aggregation point 118 (shown in FIG. 1). The aggregation point serves as a point of presence (POP) on a standard communications network, such as the Internet, for all devices within or communicating via the power line communications system 100, such as the processor system 210.

Other devices 260 can also access the external network 250 using a network service provider (NSP) 270. According to one or more embodiments of the invention, the network service provider 270 provides access to the network 250 and/or applications via the network 250 for the devices 260. For example, the network service provider can serve as an Internet service provider (ISP), an application service provider (ASP), an email server or host, a bulletin board system (BBS) provider or host, a point of presence (POP), a gateway, a proxy server, or other suitable connection point to such a network for the devices 260. As shown in FIG. 2, multiple devices 260 can use a single network service provider 270 to access the network 250. It will be understood that, although only a single network service provider 270 is shown in FIG. 2, multiple network service providers 270 can connect to the network 250, each of which can provide access to the network 250 for one or more devices 260.

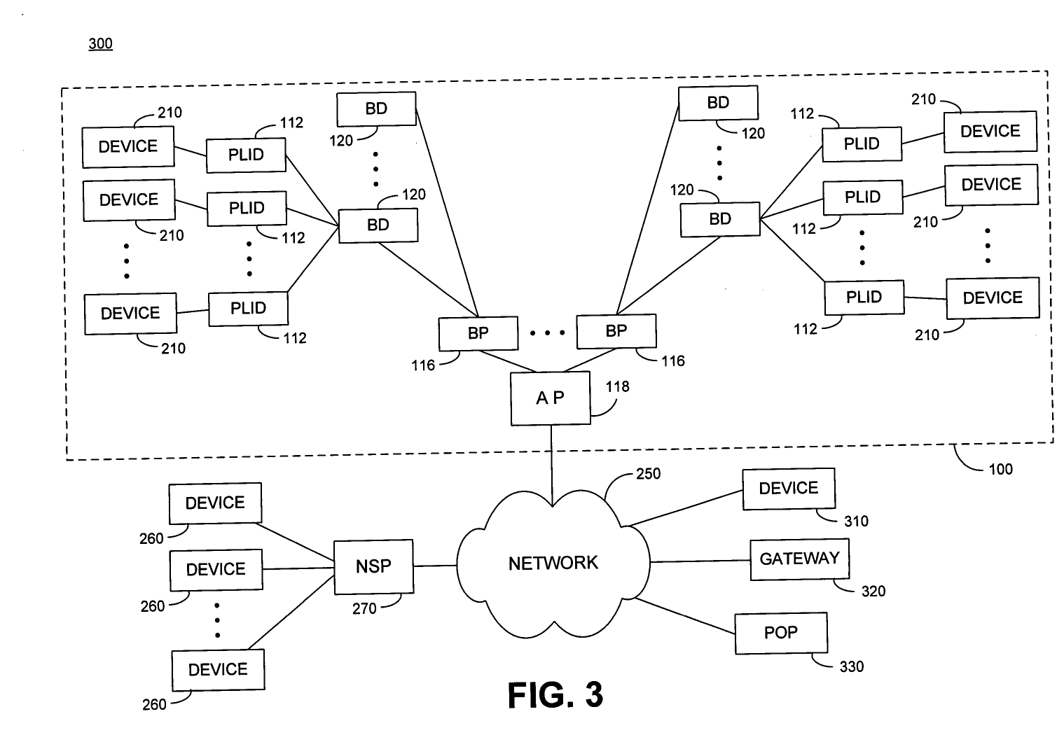

FIG. 3 is a block diagram of an example network system 300 that includes a PLCS with which an embodiment of the invention may be used. The network system 300 shown in FIG. 3 includes the power line communications system 100, which is shown in communication with the network 250. The block diagram of FIG. 3 is intended to show in greater detail how the power line communications system 100 might interface with a standard or external network 250, and devices in communication with that network 250. It should be understood that, although the processor system was shown as being outside of the power line communications system 100 in FIG. 2, they can also be considered within the power line communications system 100, as shown in FIG. 3, according to one or more embodiments of the invention.

In the network system 300 in FIG. 3, a power line communications system 100 is shown having multiple devices 210 (e.g., processor systems) in communication with multiple power line interface devices 112. Although only one device 210 is shown connected to each power line interface device 112, according to one or more embodiments of the invention, it is possible for multiple devices 210 to be in communication with a single power line interface device 112. One or more power line interface devices 112 may be in communication with a bypass device 120, which communicates with a backhaul point 116. Each bypass device 120 may communicate with multiple power line interface devices 112. Similarly, each backhaul point 116 may communicate with multiple bypass devices 120.

Each bypass device 116 acts as an interface or gateway for the multiple devices 210 within the power line communications system 100 that are in communication with the bypass device 116. More specifically, each bypass device 116 acts as an interface or gateway between the medium voltage power line and a non-power line communications medium, which may be communicatively coupled to an aggregation point or POP. The power line communications system 100 may include an aggregation point that is capable of communicating with multiple backhaul points 116 and may aggregate data from one or more backhaul points 116. The aggregation point 118 may act as a point of presence (POP) for those backhaul points 116 (and the devices 210 in communication therewith).

Multiple devices 260 outside of the power line communications system 100 can communicate with the external network 250 (e.g., the Internet) by way of a network service provider 270, as discussed above. The network service provider 270 can provide each of the devices 260 connected thereto with one or more services related to the network 250. For example, the network service provider 270 can provide email access, transmission control protocol (TCP) data, IP data, web page downloads, network application access, general network connectivity, and so forth.

In addition to the devices 260 connected to the network 250 via the network service provider 270, one or more devices 310 can be connected to the network 250 in different ways. For example, a device 310, which can be similar to or different from the processor system 210 (shown in FIG. 2), can be connected to the network 250 directly, without any network service provider 270. Moreover, a gateway 320 or a point of presence (POP) 330 can be connected to the network 250. Each of these devices can provide access to the network 250 for multiple devices connected thereto (not shown). It should be recognized, however, that a gateway 320 and a point of presence 330 also can be considered a network service provider 270. Similarly, any device 310 accessing the network 250 directly, can act as a network service provider 270 for one or more devices.

In many of the embodiments described in detail below, the system or method first determines user location information. This information can be related to the specific location or the general area of the user. The information may be determined through analytical means or may be requested of either a network service provider or a third party. In response to the request, the third party or the network service provider can provide the requested user information. Optionally, the system or method can request the information directly from the user, and the user can respond directly to provide the requested information. In some embodiments, more specific location is determined. Depending on the embodiment, and often based on the specific or general location information, the method of system may determine whether or not the user location is enabled for power line communications system service and if so, provide an offer to the user.

A request for information can be made in any way suitable to convey to the receiving party (e.g., the user, the NSP, or the third party) what information is desired regarding the user. For example, according to one or more embodiments of the invention, a computer system (e.g., a web server) can request information using a network communications technique (e.g., email, instant messaging, etc.), or other suitable techniques (e.g., postal mail, telephone communications, etc.). The information requested by the computer system can include a variety of information of interest, such as an address or general location (e.g., city, state, zip code, area code, telephone prefix, IP address, etc.) of a customer location associated with the user, or other information (e.g., network usage, browsing habits, demographic information about the user, psychographic information about the user, etc.).

Alternatively, user information can optionally be provided by the network service provider, a third party, or the user (either via the network service provider, a third party, or directly) without receipt of a request from the communications system. For example, a third party may obtain information about a user through techniques unrelated to the communications system (e.g., via surveys, purchased customer lists from an NSP or others, etc.). This information can be provided to the communications system on a selected basis when the communications system requests user information from the third party that the third party already possesses. If the third party does not possess the information, however, it can also request the information from the network service provider or the user.

User information obtained by the computer system (whether obtained from the network service provider, the third party, or directly from a user) allows the computer system to determine whether or not to provide an offer to the user. If it is determined that an offer should be provided, the computer system can provide such an offer indirectly to the user by way of the network service provider or using a third party, as desired. Alternately, the computer system can provide information of those users to whom an offer should be provided to a second computer system that provides the offer.

If offer is provided to a user using a network service provider, the offer can be provided from the network service provider, for example, as an email offer, a postal mailing offer, a telephone offer, an advertising offer, or the like. Alternatively, the computer system can actually provide an offer directly to a user, either by the same means available to the network service provider, or by alternate means.

The computer system can provide an offer indirectly to the user using a third party. For example, the computer system can request a third party to provide an offer to a user, which the third party can provide to the user either directly or indirectly (e.g., via a network service provider). For example, the third party can provide an offer directly to a user using targeted mailings (e.g., electronic, postal, etc.), other network communications, telephone calls, advertising, or any other suitable means possible. The information of users to whom an offer should be provided can be stored in memory (e.g., a database) and used to transmit automated email or automated postal mailing.

According to one or more embodiments of the invention, where the third party is an entity that runs a third-party website, an advertising offer can be placed on that third-party website when it is detected that the user is using that website. One example of such a technique can be executed where the third party operates a search engine or is responsible for advertising on a search engine. In such a scenario, when the user requests information regarding pertinent topics (e.g., regarding power line communications systems, etc.), the third party can determine information regarding the user's location and determine whether or not such service is available at the user's location. In other embodiments, the search engine or other website may provide such advertising irrespective of what kind of search, if any, is performed. Information regarding the user's location can be provided either intentionally (e.g., by a form, survey, etc.) or unintentionally. If it is determined that the user is in a location that is enabled by a power line communications system, then advertising could be correlated with the search results presented to the user, either in the form of graphical advertising, banner ads, pop-up ads, sponsored links, and so forth. It may also be desirable to determine whether the user already has broadband access, and if so, at what cost. If the cost is determined, the offer may then be customized to be more desirable than the existing broadband service of the user.

According to one or more embodiments of the invention, the user can unintentionally provide location information simply by accessing the website and making the user's IP address known to the third party, the third party can, in some cases, determine the geographic location of the user. Alternatively, information, such as an IP address can be transmitted to the communications system by the third party, and the communications system or its affiliates can dynamically determine the geographic location of the user from the IP address. For example, according to one or more embodiments of the invention, the invention, either the third party or the communications system or its affiliates can use a translation application such as the IP2Location application available from the Hexa Software Development Center (HSDC) of Penang, Malaysia.

Several techniques for determining service availability for a user, and providing an offer to a user for such service (e.g., attempting to solicit the user as a customer) are described below and in the associated figures. Although the remaining figures illustrate alternative techniques for determining service availability for a user and providing an offer to that user, it should be recognized that aspects of each of these techniques can be incorporated in the other techniques, where the techniques are compatible and where such a combination is feasible and desirable.

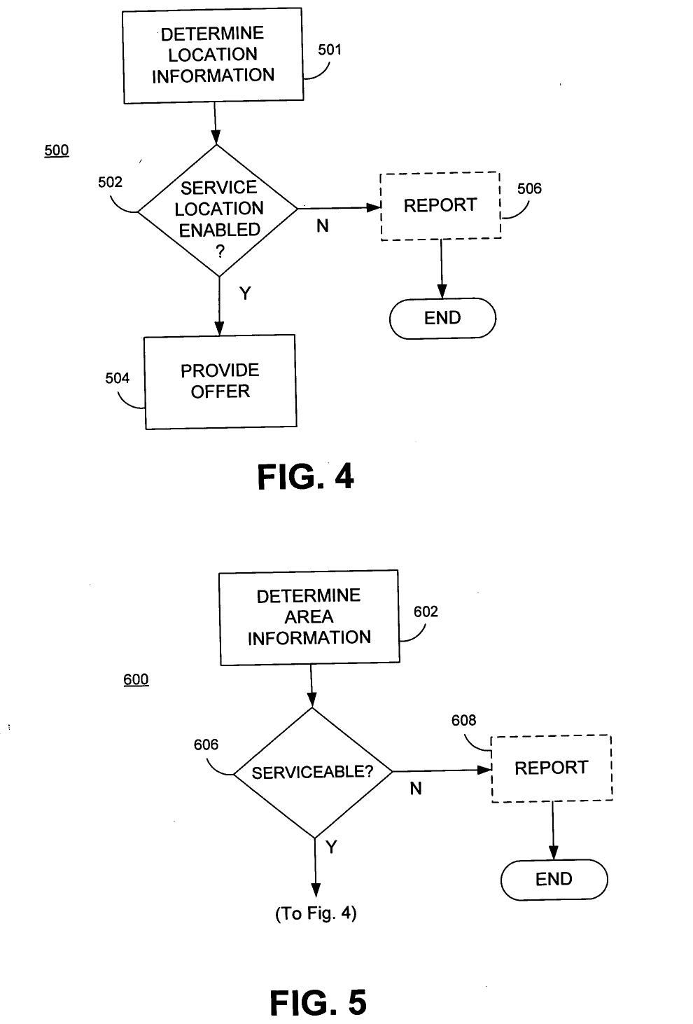

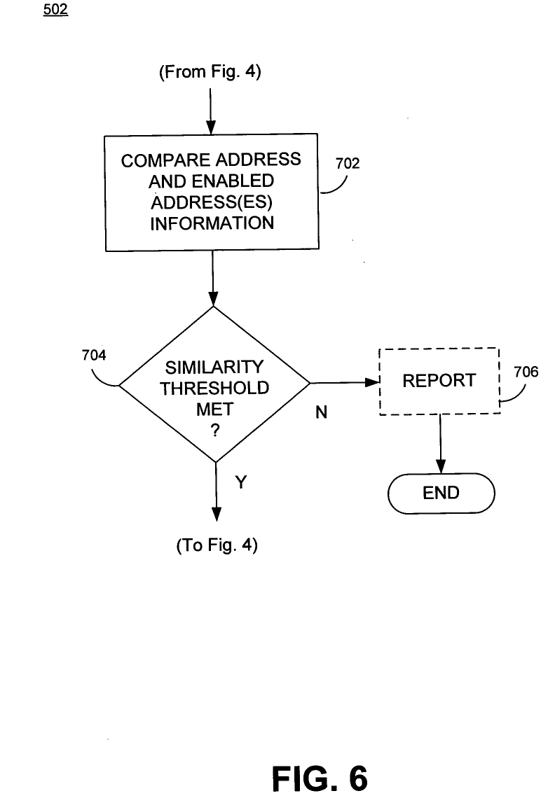

FIG. 4 is a flow diagram of a technique 500 for determining service availability and for providing an offer, according to an embodiment of the invention. In the technique 500 illustrated in FIG. 4, at step 501 user location information is determined followed by a general determination of whether or not the user location is enabled occurs in step 502. If the user location is enabled, an offer can be provided in step 504 to the user associated with that location. On the other hand, if it is determined in step 502 that the user location is not enabled, then the technique 500 optionally can report in optional step 506 that there is no service availability, and the technique ends. Information reported in step 506 can be stored in a database, and can be used for different purposes (e.g., to determine the desirability of expanding a communications system to an area in which multiple unsuccessful determinations have occurred).

According to one or more embodiments of the invention, the technique 500 shown in FIG. 4 can be executed by a processor (e.g., by a processor system 210 or similar device) via a network connection. For example, the steps shown in FIGS. 4 (as well as the remaining figures) can be in the form of computer code representing instructions to cause a processor to perform the technique 500.

The determination of location information in step 501 can occur in one of many ways, some of which have been discussed above. For example, an IP address of a user device can be analyzed to dynamically determine a geographical location (e.g., a street address, community, neighborhood a street, a zip code, a city, a county, etc.). The user location information is compared to locations that are enabled, and if it is determined that the geographic location associated with that user location information (e.g., street address, street, city, etc.) is enabled, then the determination in step 502 is positive. Location information for a user can be obtained through one of many ways (e.g., via a third party vendor, via a network service provider, directly from a user, from a survey, etc.). If it is determined that the address of the user is enabled, then an offer can be provided in step 504.

FIG. 5 is a flow diagram of a technique 600 for determining service availability, according to an embodiment of the invention. The technique 600 shown in FIG. 5 is a technique that can be used to supplement the technique 500 shown in FIG. 4. Specifically, the steps shown in FIG. 5 can precede the determination 502 of FIG. 4, and the technique 600 of FIG. 5 can continue in the technique 500 of FIG. 4.

The technique 600 shown in FIG. 5 represents one alternative technique for determining general serviceability of a user location by determining general area information of a user and deciding whether that general area is an area where power line communications systems are offered. After this occurs, the technique 500 shown in FIG. 4 can further specifically determine for the specified user whether the user's location is enabled (e.g., in step 502 of FIG. 4).

The technique 600 shown in FIG. 5 begins by the determination of the general area of the user in step 602, or by receiving the general area information of the user. The determination made in step 602 can include determining the general area of a user from one or more possible parameters that can be requested by and/or communicated to a computer system. For example, the user's IP address, zip code, area code, telephone prefix, city, state, or other information can be used in step 602 to determine the general geographic area of a user. This information can be obtained by one of a variety of means. For example, the information can be obtained from a third party, such as a data-mining corporation, network service provider, or other third party vendor. Alternatively, the information can be dynamically determined from network activities of a user. For example, Internet history or cookie information can be used to determine a general area of a user. Alternatively, an IP address of a user can be resolved and associated with a general area, as discussed above. Also, information regarding a user's location can be determined from a telephone modem number used by the user to access a network service provider, or from the location of the network service provider used by the user. The general area need not be a contiguous area, but instead could be a plurality of non-contiguous land areas such as, for example, separate towns.

Another method for determining the general geographical area of the user in step 602, is that such information can be provided. For example, the user can fill out a survey providing such information. Alternatively, a network service provider or other third party can provide such information (e.g., pursuant to a customer agreement with the user).

Once the general area of the user has been determined in step 602, a determination is made in step 606 regarding whether the general area in which the user is located is serviceable (at least in part). For example, in a case where a zip code or city is determined for a user, and that zip code or city correspond to an area where power line communication services are offered, that general geographic area can be determined to be serviceable in step 606. If the location of the user is determined in step 606 not to be serviceable, a report can be generated 608 (and stored, if desired), and the technique 600 ends. From the report information generated in step 608, proprietors of power line communications systems can determine the desirability of installing a power line communications system in a general geographic location for which the determination of step 606 has been unsuccessfully made. Once it is determined that the general location of the user is serviceable in step 606, the technique 600 continues with the technique 500 illustrated in FIG. 4.

FIG. 6 is a flow diagram of a technique 502 for determining service availability, according to an embodiment of the invention. The technique 502 shown in FIG. 6 is one technique in which it can be determined whether a user location is enabled in step 502 of FIG. 4. This determination is made by comparing a user's location information (e.g., such as a street address, county, street, etc.) with information of enabled locations in step 702. For example, according to one or more embodiments of the invention, the street address of a user can be compared with a list of enabled street addresses to determine if the user's address is on the list.

In step 704, it is determined whether the user's location information (e.g., such as a street address, county, street, etc.) and information of enabled locations are within a similarity threshold. For example, where a user's street address is compared to a list of enabled addresses, the user's address may be on the list of enabled addresses, but may be listed in a slightly different format (e.g., using approved postal abbreviations, etc.). Alternately, and as another example, where a user's street (e.g., when the user's specific address is unknown) is compared to a list of enabled addresses, the user's street may be on the list of enabled addresses, while not all addresses on the street are listed. In some embodiments similarity threshold will have been met, as determined in step 704, and the user will be provided with an offer in step 504 (shown in FIG. 4). If, on the other hand, a similarity threshold is not met in step 704, then a report can be generated in step 706, and the technique 502 ends.

As discussed, information more general than a specific street address may used in the comparison. For example, medium voltage power lines used by many PLCSs often run along a street, which may be enabled in its entirety. Consequently, in some embodiments a street name may be compared with a list of enable streets to provide the comparison (e.g., even if the specific user address is known). Likewise, neighborhoods or communities are often served off the same medium voltage power line and may be enabled in its entirety. Therefore, a neighborhood, community, complex, township, or other such information may be compared with a list of similar areas. In addition, information of enabled areas may also comprise areas that are to be enabled in the near future such as one week, a month, or two months.

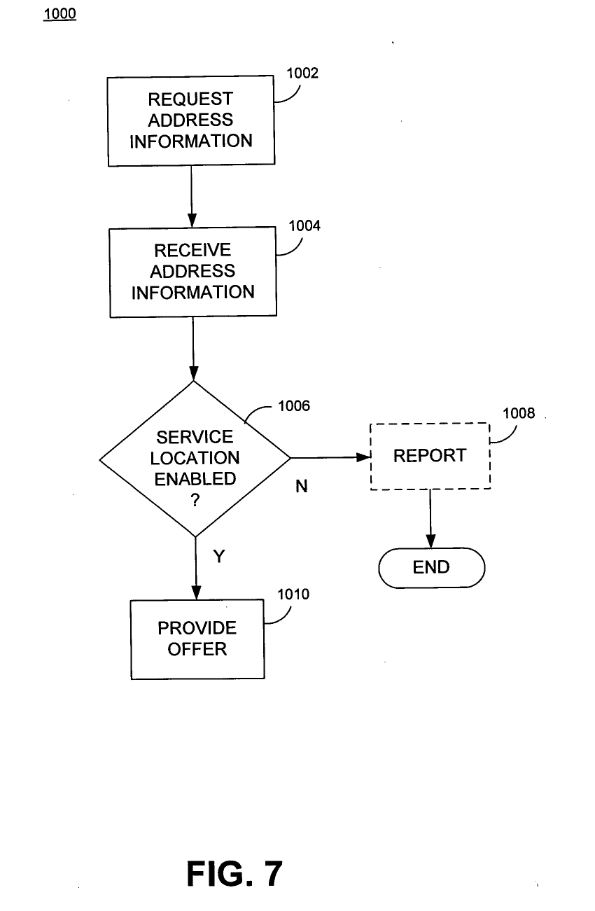

FIG. 7 is a flow diagram of a technique 1000 for determining service availability and for providing an offer, according to an embodiment of the invention. The technique 1000 illustrated in FIG. 7 begins by requesting address information of a user in step 1002. This information is received in step 1004, and a determination is made in step 1006 regarding whether or not the location of that user is enabled. If the location of the user is not enabled, as determined in step 1006, then a report can be optionally generated in optional step 1008, and the technique 1000 ends. Alternatively, however, if it is determined in step 1006 that the location of the user is enabled, an offer can be provided to that user in step 1010. The steps in this process (such as steps 1002 and 1004) may form part of another process, such as the user providing address information when completing an online purchase form. The determination step 1006 in FIG. 7 may be accomplished in any suitable manner such as those described for step 502 in FIGS. 4 and 6.

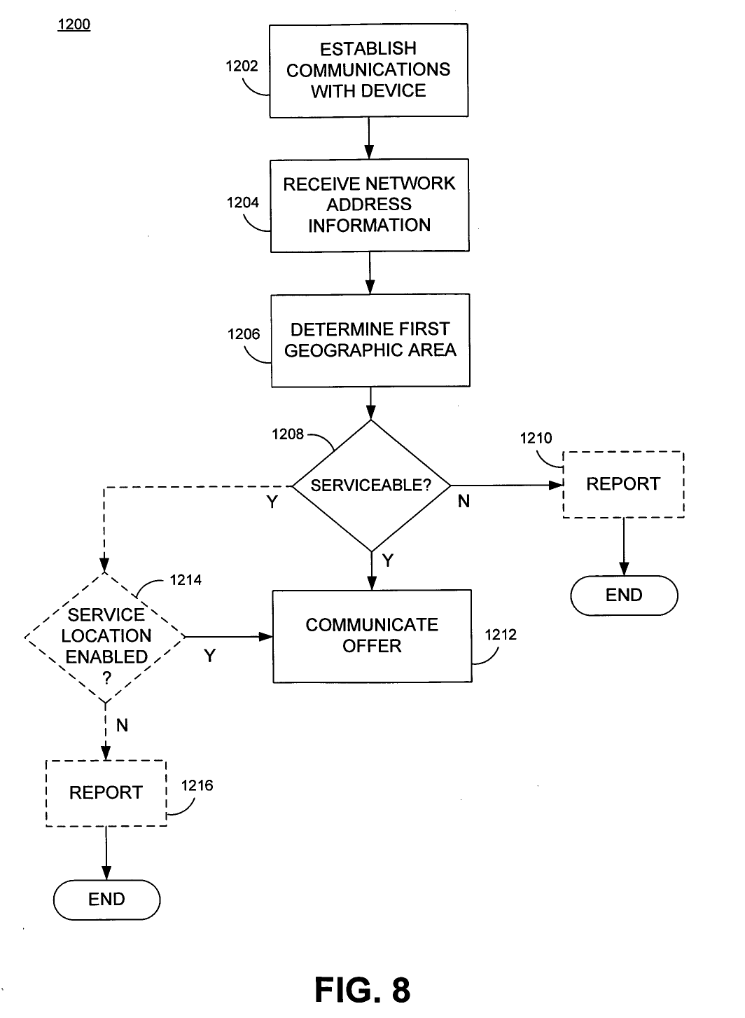

FIG. 8 is a flow diagram of a technique 1200 for determining service availability and for communicating an offer, according to an embodiment of the invention. The technique 1200 begins at step 1202 by establishing communications with a user's device, which may be located at a customer location, for example. As will be evident to those skilled in the art, the step of establishing communications with a user device may also be employed in other embodiments herein. Network address information is received from the user's device in step 1204, either in response to a request from a computer system or by other means. For example, a user's IP address may be obtained dynamically when the user accesses a network site.

In step 1206, a first geographic area associated with the user is determined. The first geographic area can be, for example, determined automatically from the network address information received in step 1204, or by other means. For example, the first geographic area can be determined from information possessed by a third party or a network service provider, which is communicated to the computer system. Once the first geographic area has been determined, a determination is made in step 1208 regarding whether the first geographic area is serviceable. As will be evident to those skilled in the art, the determination in step 1208 may be accomplished via the method described elsewhere herein such as, for example, in the descriptions associated with FIGS. 4-6. If it is determined in step 1208 that the first geographic area is not serviceable, an optional report can be generated in optional step 1210, and the technique 1200 ends. Alternatively, if it is determined that the first geographic area is serviceable, an offer can be communicated in step 1212. The offer can be communicated in step 1212 either directly or indirectly (e.g., via a third party, an NSP, etc.), in any manner suitable for the offer being communicated.

As an alternative, prior to communicating an offer in step 1212, an additional determination can optionally be made in optional step 1214 regarding whether or not the specific location of the user is enabled. If it is determined in step 1214 that the specific location of the user is enabled, then the offer can be communicated in step 1212. If it is determined in step 1214 that the location is not enabled, such a determination can optionally be reported in optional step 1216, and the technique 1200 ends. According to one or more embodiments of the invention, multiple offers can be provided in step 1212 after each determination 1208, 1214 of the technique 1200 or in any of the embodiments herein. For example, a generalized offer can optionally be made in step 1212 after it is determined in step 1208 that the first geographic area is serviceable, and a more specific offer can be made in step 1212 after it is determined in step 1214 that the specific location of the user is enabled. According to such an embodiment, the computer system can sample interest for a service in a general geographic area where services are offered, even if service to the user's specific location may not be available.

In another embodiment, a power line communication system network element (e.g. a device communicatively coupled to an MV power line) may include a wireless transceiver and may detect a customer premises wireless network. Upon detection, the network element may communicate the offer directly, or provide information of the detection to a remote computer system that transmits the offer. In either instance, the transmission may be accomplished via the wireless transceiver of the network element. In some instances, the wireless network may be inaccessible, in which case the offer may be transmitted via any other suitable method described herein with the destination determined by those customer premises from which the network element could detect the wireless network (e.g., those customer premises on that street block) and that do not already have the PLCS service. Preferably, the detection and offer transmission are automated in software.

In another similar embodiment, a network element may detect a Homeplug or other in-home power line network via the low voltage power lines. Upon detection, the network element may communicate the offer directly, or provide information of the detection to a remote computer system that transmits the offer. In either instance, the transmission may be accomplished via the low voltage power lines by the network element. In some instances, the power line in-home network may be inaccessible, in which case the offer may be transmitted via any other suitable method described herein with the destination determined by those customer premises to which the network element is communicatively coupled via the low voltage power lines and that do not already have the PLCS service. Preferably, the detection and offer transmission are automated in software.

From the foregoing, it can be seen that a system and method for determining service availability and soliciting customers are discussed. Specific embodiments have been described above in connection with determining availability of network service using a power line communications system for one or more users, and providing or communicating an offer to one or more users for whom such network service is available. In addition, it will be evident to those skilled in the art that not all steps in each embodiment are necessary and that steps in some embodiments may be used in other embodiments. While many of the above embodiments are described as being performed by a computer system, such as a web server, (which may be substantially similar to a processor system 210), the steps in the embodiments may be performed by numerous computer systems that may be co-located or remote from each other.

It will be appreciated, however, that embodiments of the invention can be in other specific forms without departing from the spirit or essential characteristics thereof. For example, while some embodiments have been described in the context determining availability of and providing an offer for network service relating to a power line communications system, the techniques described above can be used in a variety of other contexts. Moreover, although many examples of offers provided specifically to individual users have been provided, general offers can be made to multiple individuals (e.g., in the form of general advertising, mass-mailings, etc.) in areas where significant interest in communications systems exists (e.g., as determined by inquiries by individuals in non-serviceable areas, etc.), or where it is desired to generate such interest (e.g., as determined by demographic information, etc.). Additionally, it should be appreciated that all components, network configurations, and techniques are examples of possible implementations, but can be modified as dictated by design requirements or other parameters.

The presently disclosed embodiments are, therefore, considered in all respects to be illustrative and not restrictive.

What is claimed is:

1. A method, comprising:
determining a general area of a customer location;
determining whether the general area is at least partially coincidental with a service area where a power line communications service is available;
determining if the customer location is enabled for the power line communications service, if it is determined that the general area is at least partially coincidental with a service area where a power line communications service is available; and
providing an offer related to the power line communications service to an entity associated with the customer location, if it is determined that the customer location is enabled.

2. The method of claim 1, wherein the determining if the customer location is enabled comprises:
comparing at least a portion of an address of the customer location with information of at least one enabled address, the information of the at least one enabled address corresponding to an address that is enabled for the power line communications service; and
determining if the at least a portion of the address of the customer location is substantially similar to at least a portion of the information of at least one enabled address.

3. The method of claim 1, wherein the determining a general area comprises using at least a portion of a network address associated with the customer location.

4. The method of claim 1, wherein the determining a general area comprises receiving information from a network service provider relating to the customer location.

5. The method of claim 1, wherein the determining if a customer location is enabled comprises comparing information of the customer location with information of enabled locations.

6. The method of claim 1, wherein the determining if a customer location is enabled comprises comparing at least a portion of an address of the customer location with a subset of a plurality of enabled addresses associated with a power line communications network.

7. The method of claim 6, wherein the comparing comprises comparing at least a portion of an address of the customer location with a subset of a plurality of enabled addresses associated with a medium voltage power line.

8. The method of claim 1, wherein the providing comprises providing targeted advertising via a network.

9. The method of claim 1, wherein the providing comprises providing a targeted email offer.

10. The method of claim 1, wherein the providing comprises providing a targeted direct mail offer.

11. The method of claim 1, wherein the providing comprises providing a targeted telephone offer.

12. The method of claim 1, further comprising requesting an address of the customer location.

13. The method of claim 12, wherein the requesting comprises requesting the address from an entity associated with the customer location.

14. The method of claim 12, wherein the requesting comprises requesting the address from a third party.

15. The method of claim 14, wherein the third party comprises a network service provider.

16. The method of claim 1, further comprising receiving a response from the offer.

17. The method of claim 16, wherein said response comprises a request for service.

18. The method of claim 16, wherein said response comprises credit card information.

19. A processor-readable medium comprising code representing instructions to cause a processor to:
determine if a customer location is enabled for a power line communications service; and
provide an offer related to the power line communications service to an entity associated with the customer location, if it is determined that the customer location is enabled.

20. The processor-readable medium of claim 19, wherein the code representing instructions to cause a processor to determine if a customer location is enabled comprises code to cause a processor to:
determine a general area of the customer location; and
determine whether the general area comprises a service area where a power line communications service is available.

21. The processor-readable medium of claim 20, wherein the code representing instructions to cause a processor to determine a general area includes code representing instructions to cause a processor to use at least a portion of a network address associated with the customer location to make the determination.

22. The processor-readable medium of claim 20, wherein the code representing instructions to cause a processor to determine a general area comprises code representing instructions to cause a processor to receive information from a network service provider about the customer location.

23. The processor-readable medium of claim 19, wherein the code representing instructions to cause a processor to determine if a customer location is enabled comprises code to cause a processor to:
compare at least a portion of an address of the customer location with information of at least one enabled address, the information of the at least one enable address corresponding to an address that is enabled for the power line communications service; and
determine if the at least a portion of the address of the customer location is substantially similar to at least a portion of the information of at least one enabled address

24. The processor-readable medium of claim 19, wherein the code representing instructions is configured to cause a processor to execute at least one of the instructions via a network server.

25. The processor-readable medium of claim 24, wherein the network server serves a search engine, the code representing instructions being configured to cause a processor to execute at least one of the instructions via a search engine.

26. The processor-readable medium of claim 24, wherein the network server serves a search engine, the code representing instructions being configured to cause a processor to execute at least one of the instructions via a network service provider.

27. The processor-readable medium of claim 19, wherein the code representing instructions to cause a processor to provide comprises code to cause a processor to provide targeted advertising via a network.

28. The processor-readable medium of claim 19, wherein the code representing instructions to cause a processor to provide comprises code to cause a processor to provide a targeted email offer.

29. The processor-readable medium of claim 19, wherein the code representing instructions to cause a processor to provide comprises code to cause a processor to request a targeted direct mail offer to be provided.

30. The processor-readable medium of claim 19, wherein the code representing instructions to cause a processor to provide comprises code to cause a processor to cause a targeted telephone offer to be provided.

31. A method, comprising:
requesting an address of a customer location;
determining if the address of the customer location is enabled for a power line communications service; and
providing an offer to an entity associated with the customer location related to the power line communications service, if the address of the customer location is enabled for the power line communications service.

32. The method of claim 31, wherein the determining comprises:
comparing at least a portion of the address of the customer location with information of at least one enabled address that draws power from a power line that has been enabled by a bypass device; and
determining if the at least a portion of the address of the customer location is substantially similar to at least a portion of the information of at least one enabled address.

33. The method of claim 31, wherein the determining comprises:
comparing at least a portion of an address of the customer location with a subset of a plurality of predetermined enabled addresses associated with a power line communications network.

34. The method of claim 33, wherein the comparing comprises comparing at least a portion of an address of the customer location with a subset of a plurality of predetermined enabled addresses associated with a medium voltage power line.

35. The method of claim 31, wherein the requesting comprises requesting the address from an entity associated with the customer location.

36. The method of claim 31, wherein the providing comprises providing targeted advertising via a network.

37. The method of claim 31, wherein the providing comprises providing a targeted email offer.

38. The method of claim 31, further comprising receiving a response from the offer.

39. The method of claim 38, wherein said response comprises a request for service.

40. The method of claim 38, wherein said response comprises credit card information.

41. A processor-readable medium comprising code representing instructions to cause a processor to:
request an address of a customer location;
determine if the address of the customer location is enabled for a power line communications service; and
provide an offer to an entity associated with the customer location to subscribe to the power line communications service, if the address of the customer location is enabled for power line communications service.

42. The processor-readable medium of claim 41, wherein the code representing instructions to cause a processor to request includes code to cause a processor to request the address.

43. The processor-readable medium of claim 42, wherein the code representing instructions to cause a processor to request comprises code to cause a processor to request the address as part of an purchase form.

44. The processor-readable medium of claim 42, wherein the code representing instructions to cause a processor to request comprises code to cause a processor to request the address as part of a survey.

45. The processor-readable medium of claim 42, wherein the code representing instructions to cause a processor to request comprises code to cause a processor to request the address from a network service provider.

46. A method, comprising:
establishing a communication link with a device;
receiving information of a network address of the device;
determining a first geographic area of the device based on the information of the network address;
determining if the first geographic area is at least partially coincidental with at least one power line communications service area; and
if the first geographic area is at least partially coincidental with at least one power line communications service area, communicating an offer related to the power line communications service.

47. The method of claim 46, further comprising:
determining whether the device is located in a power line communications service area if the first geographic area is at least partially coincidental with at least one power line communications service area.

48. The method of claim 47, wherein determining whether the device is located in a power line communications service area comprises:
determining the location of the device; and
determining whether the location of the device is within a service area.

49. The method of claim 48, wherein the location of the device comprises address information, the determining whether the location of the device is within a service area comprising comparing the address information with service area address information.

50. The method of claim 49, wherein the address information comprises street information.

51. The method of claim 49, wherein the address information comprises a mailing address.

52. The method of claim 49, wherein the address information comprises zip code information.

53. The method of claim 49, wherein the address information comprises area code information.

54. The method of claim 49, wherein the address information comprises telephone prefix information.

55. The method of claim 49, wherein the address information comprises city information.

56. The method of claim 46, wherein the power line communications area comprises locations to be enabled within a predetermined time period.

57. The method of claim 56, wherein the power line communications area comprises locations to be enabled within sixty days.
